(19) United States
(12) Patent Application Publication
(10) Pub. No.: US 2009/0173008 A1
(43) Pub. Date: Jul. 9, 2009

(54) PHOTOVOLTAIC CHARGED DRIVING DEVICE FOR SHUTTER

(76) Inventors: Horng-Tsann HUANG, Taichung City (TW); Ching-Hwa LIN, Taichung City (TW)

Correspondence Address: SINORICA, LLC, 2275 Research Blvd., Suite 500, ROCKVILLE, MD, 20850, US

(21) Appl. No.: 12/121,888

(22) Filed: May 16, 2008

(30) Foreign Application Priority Data
Jan. 4, 2008 (TW) 097200248

(51) Int. Cl. E06B 7/086; H01L 31/04

(52) U.S. Cl. 49/74.1; 136/244

(57) ABSTRACT

A photovoltaic charged driving device applicable to a shutter includes a driving module and a photovoltaic module. The driving module comprises a rechargeable power unit, a controller, a motor and a power input terminal, used to drive slats to change their angle. The photovoltaic module includes a power output terminal having a compatible connector with the power input terminal, and a solar panel used to receive sunlight to charge the rechargeable power unit so as to enable the driving module to chronically operate without changing a battery. The photovoltaic module can be conveniently connected to or removed from the driving module for receiving sunlight effectively.

### BACKGROUND OF THE INVENTION

1. Field of the Invention

This invention relates to a motorized shutter, particularly to one provided with a photovoltaic panel accompanied with the driving device to effectively utilize sunlight to supplement its battery power.

2. Brief Description of the Prior Art

Shutter is a kind of window covering structured with a frame and movable slats against a window. Plural slats are pivotally mounted across two corresponding sides of the frame for being rotated to adjust the sunlight passing through. A pulling rod is pivotally connected with the middle portions of the slats for a user to manually adjust the slats to alter their angle.

As disclosed in US publication No. 2008/0000157, a motorized shutter mainly includes a driving module settled in a recess of its side frame and composed of a power supply, a motor, a gear set, an output shaft and a controller. With the controller operated by a user, the motor is driven to successively rotate the gear set and the output shaft, that is connected to an end of a slat, so that the slats connected together by a pulling rod can be rotated to a desired angle. The power supply used to drive the driving module is batteries. Although the module using batteries does not need messy power cords to connect to an AC power supply or an adaptor, the batteries have to be replaced with new ones once the batteries run out.

U.S. Pat. No. 7,178,291 discloses an automated shutter having a motor installed at its side frame to control a slat connector piece fixed at one of the slats that are linked together by a pulling rod so as to be simultaneously moved. The motor can be driven by a solar energy storage device. The solar panel is mounted on the outside of the motor housing. As the housing and solar panel is fixed with the shutter, it is impossible to be properly adjusted to get sufficient solar energy in case that the solar panel is not located under adequate sunlight exposure.

Moreover, some other shutters or blinds, as revealed in US Publication Nos. 2007/0175599 and 2007/0215200, and Japan Patent No. 02308086, are powered by solar energy, having solar panels fixed on and moved together with their slats or blind members, making special solar panel assemblies that are totally different from conventional shutter constructions. However, they are rather complicated and expensive. Therefore, the present invention has been devised to overcome the defects mentioned above.

### SUMMARY OF THE INVENTION

The major object of the invention is to provide a photovoltaic charged driving device applicable to a common window shutter.

A further object of the invention is to provide a photovoltaic charged driving device for a shutter that a solar panel can be mounted apart.

The main characteristics of the invention are a driving module and a photovoltaic module. The driving module used to drive the slats to change their angle comprises a rechargeable power unit, a controller, a motor and a power input terminal. The photovoltaic module includes a power output terminal having a compatible connector with the power input terminal, and a solar panel (solar cell) used to transform sunlight into electricity and charge the rechargeable power unit. The photovoltaic module can be installed together with or separately from the driving module. In case that the photovoltaic module and the driving module are independently installed, they are linked by an electric cord terminated with compatible connectors for power transmission. When the electric cord is removed, the photovoltaic module can be as well assembled together with the driving module by means of the compatible connectors provided respectively on the power output terminal and the power input terminal. In an embodiment, the electric cord can have its two ends fixedly positioned on the photovoltaic module and the driving module respectively, and with all or part of it packed in the driving module.

Since a shutter is generally installed inside a window exposed to sunlight, the photovoltaic charged driving device of the invention thus takes advantage of a solar panel to provide power for charging a battery (or other rechargeable power units) of the driving module, so it is not necessary to often change a battery. If necessary, the photovoltaic module can be installed independently from the driving module so as to obtain sufficient sunlight and provide more power to charge the driving module.

### BRIEF DESCRIPTION OF DRAWINGS

This invention is better understood by referring to the accompanying drawings, wherein:

FIG. 1 is a descriptive view of a photovoltaic charged driving device according to the invention, showing it being installed in a shutter;

FIG. 2 is a partial view of the embodiment of FIG. 1 showing the driving module in the device and the slats of the shutter;

FIG. 3 is a perspective view of a separated driving module and a photovoltaic module in a first embodiment of the invention;

FIG. 4A is a partially exploded view of a driving module in the first embodiment of the invention;

FIG. 4B is a partial exploded view of a driving module in a second embodiment of the invention;

FIG. 5 is a descriptive view of a driving module and a photovoltaic module of a third embodiment of the invention;

FIG. 6 is a descriptive view of a driving module and a photovoltaic module of a fourth embodiment of the invention; and

FIG. 7 is an exploded view of a photovoltaic module in an embodiment of the invention.

### DETAILED DESCRIPTION OF THE PREFERRED EMBODIMENT

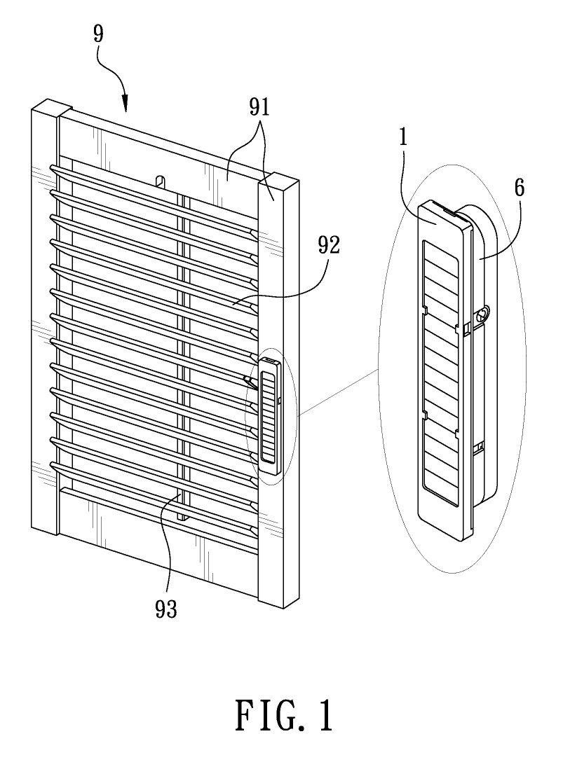

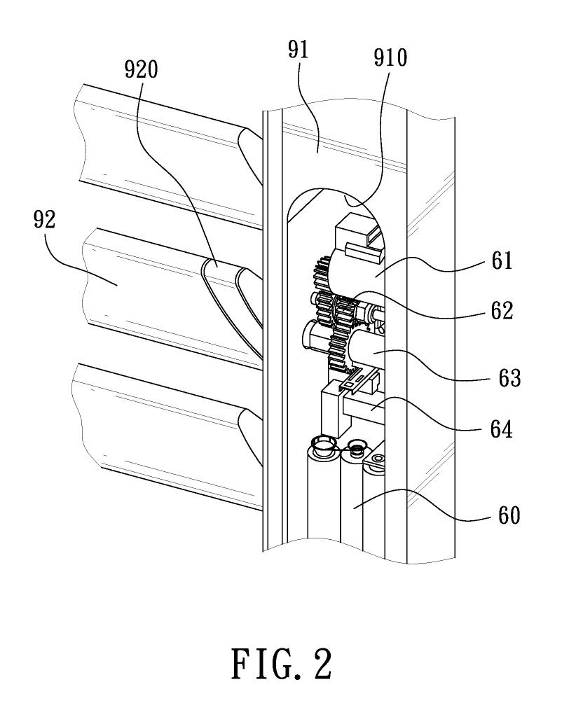

As shown in FIGS. 1 and 2, a photovoltaic driving device for a shutter according to the invention includes a driving module 6 installed in a recess 910 bored in an inner side frame 91 of a shutter 9 and a photovoltaic module 1 assembled with the driving module 6, employed to adjust an angle of slats 92 of the shutter 9.

The driving module 6 is provided with a rechargeable power unit 60, a motor 61, a gear set 62, an output shaft 63 and a controller 64. The controller 64 is commanded by an input interface (not shown in the figures), such as a remote controller or a receiver, controlled by a user to actuate the motor 61 that is to orderly drive the gear set 62 and the output shaft 63 to rotate. The output shaft 63 is connected with one end 920 of one of the slats 92. Linked together by a pulling rod 93, the slats 92 can be simultaneously rotated by the output shaft 63 to position at expected angles. The rechargeable power unit 60 used in the embodiment is a chargeable battery (such as a nickel-metal hydride battery or a lithium iron phosphate battery), or a super capacitor.

The photovoltaic module 1 includes a solar panel, used to generate electricity to charge the rechargeable power unit 60 that provides power for the driving module 6. As being properly positioned aside a window to receive sunlight, the photovoltaic module 1 can appropriately generate electric power from sunlight and recruit the power consumption of the rechargeable power unit 60 for the driving module 6 without necessity of changing battery.

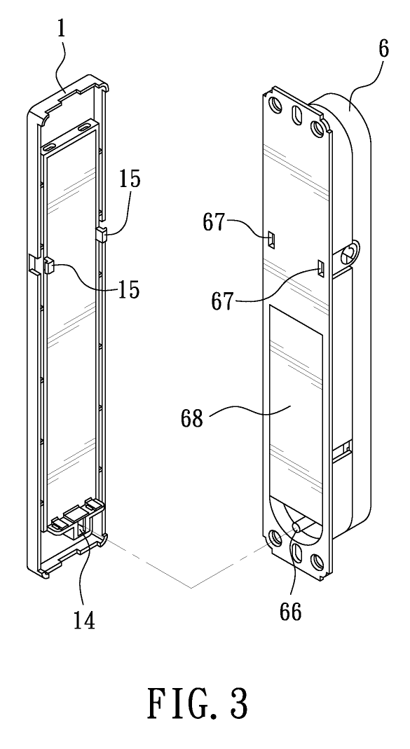

FIG. 3 is a perspective view of the photovoltaic module 1 and the driving module 6 being separated. The photovoltaic module 1 is provided with two locking hooks 15 formed at two vertical sides for correspondingly locking in two locking grooves 67 cut in the driving module 6, so as to keep the photovoltaic module 1 assembled together with the driving module 6. In addition, located at an end of the photovoltaic module 1 is a power output terminal 14 (such as an DC power socket), which is to be connected with a power input terminal 66 (such as an DC power plug) positioned at an end of the driving module 6, so that the rechargeable power unit 60 installed behind a protecting cover 68 can be charged by the photovoltaic module 1.

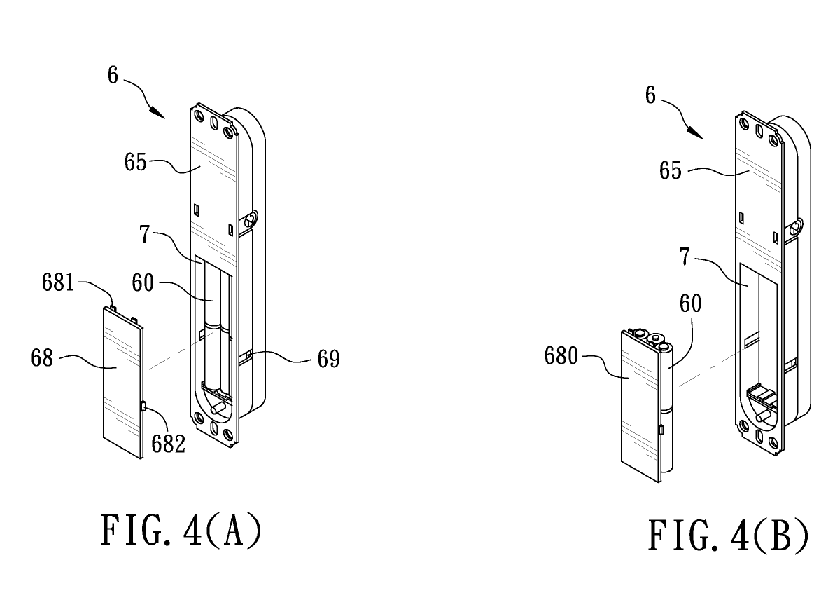

Next, as shown in FIG. 4A, a partial exploded view of the driving module 6 in the first embodiment of the invention, the driving module 6 is provided with a main body 65 having its lower portion formed as a chamber 7 for accommodating the rechargeable power unit 60. With two pairs of locking hooks 681 and 682 respectively located at the top and two sides of a protecting cover 68 to be correspondingly restricted in locking grooves 69 bored at the top and two sides of the main body 65, the chamber 7 of the driving module 6 can be capped with the protecting cover 68.

FIG. 4B shows a partial exploded perspective view of the driving module 6 in a second embodiment of the invention. The rechargeable power unit 60 is in advance fixed on a holder 680 that is to be installed in the chamber 7.

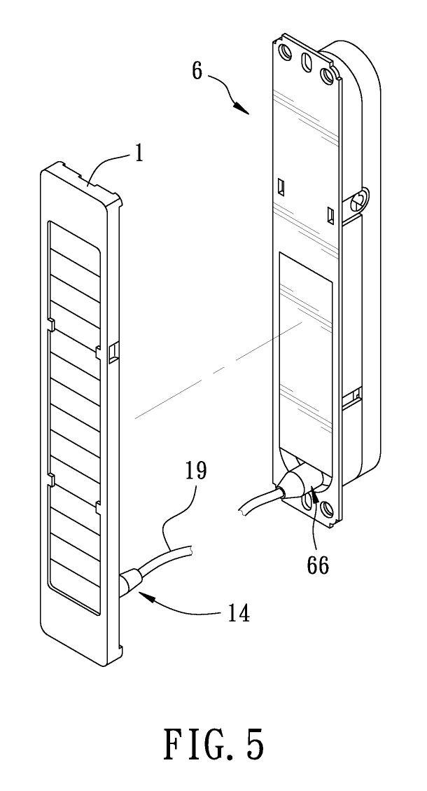

FIG. 5 shows a descriptive view of a photovoltaic module 1 and a driving module 6 in a third embodiment of the invention. In case that the photovoltaic module 1 can not adequately receive sunlight owing to the location of the shutter, it can be separately positioned from the driving module 6. For example, the photovoltaic module 1 can be attached to an appropriate position of the window glass by means of silicon glue or twin adhesive or suction cap, so as to improve the solar collection efficiency. By the time, the power output terminal 14 of the photovoltaic module 1 and the power input terminal 66 of the driving module 6 can be connected by an electric cord 19 having its two ends fastened with connecting means compatible with the power output terminal 14 and the power input terminal 66. A spirally extensible cord structure can be used as the electric cord 19 so as to adapt the distance change between the photovoltaic module 1 and the driving module 6 while the shutter is moved from closed to open position relative to the window glass.

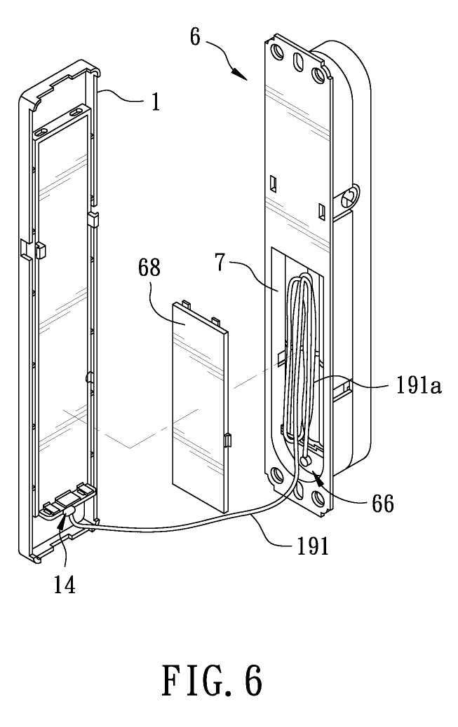

Moreover, FIG. 6 shows a descriptive view of a driving module and a photovoltaic module of a fourth embodiment of the invention. An electric cord 191 having a preset length is fixedly connected between the power output terminal 14 of the photovoltaic module 1 and the power input terminal 66 of the driving module 6, with all or part (191a) of it folded and packed in the chamber 7 of the driving module 6 or a reserved space of other portion, thus keeping the shutter neat. Of course, the photovoltaic module 1 can also be provided with some space for accommodating the electric cord 191.

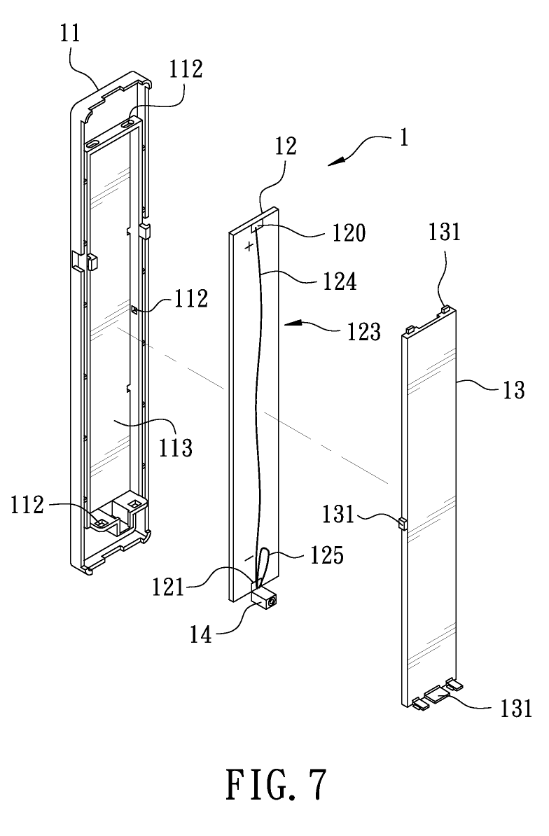

FIG. 7 is an exploded view of a photovoltaic module in an embodiment of the invention. The photovoltaic module 1 mainly comprises a frame 11 provided with an opening 113, a solar panel 12 and a rear cover 13 assembled inside the frame 11 in order. The rear cover 13 is provided with plural projections 131 formed on its back adjacent to the solar plane 12 for locking in grooves 112 formed around the opening 113 of the frame 11, so as to keep the solar panel 12 tightened between the frame 11 and the rear cover 13, with a solar cell surface 123 of the solar panel 12 exposed to sunlight through the opening 113 to create power. The solar panel 12 is also provided with a positive electrode 120 and a negative electrode 121 respectively located at its top and its bottom neighboring the back of the rear cover 13, and two conducting lines 124 and 125 respectively connected with the positive electrode 120 and the negative electrode 121 to the power output terminal 14 (such as a socket). In using, the photovoltaic module 1 is connected with the driving module 6 to enable the rechargeable power unit 60 charged by having the electric cord 191 linked between the power output terminal 14 and the power input terminal 66 of the driving module 6 or having the photovoltaic module 1 directly plugged by the driving module 6 as shown in FIG. 3.

While the preferred embodiment of the invention has been described above, it will be recognized and understood that various modifications may be made therein and the appended claims are intended to cover all such modifications that may fall within the spirit and scope of the invention.

What is claimed is:

1. A photovoltaic charged driving device installed on a preselect position of a shutter and connected to one of slats of said shutter to drive said slats to rotate to desired angles, said slats being linked together by a pulling rod so as to be simultaneously rotated by said driving device, said driving device comprising:
a driving module, installed in a recess of a side frame of said shutter to adjust the angle of said slats and provided with an output shaft connected to one end of one said slat, including a rechargeable power unit, a controller, a motor and a power input terminal; and
a photovoltaic module including a solar panel used for receiving sunlight, a power output terminal connected to said solar panel and provided with a connecting component to compatibly connect with said power input terminal so as to charge said rechargeable power unit.

2. The photovoltaic charged driving device for shutter as claimed in claim 1, wherein said photovoltaic module and said driving module are provided with corresponding locking hooks and grooves, so as to be selectively assembled together and released apart.

3. The photovoltaic charged driving device for shutter as claimed in claim 1, wherein an electric cord is removably connected between said power output terminal of said photovoltaic module and said power input terminal of said driving module by having its two ends terminated with connectors compatible with those of said power output terminal of said photovoltaic module and said power input terminal of said driving module to keep said driving module charged while said driving module and said driving module are installed separately.

4. The photovoltaic charged driving device for shutter as claimed in claim 3, wherein said electric cord is a spirally extensible structure.

5. The photovoltaic charged driving device for shutter as claimed in claim 3, wherein at least one of said photovoltaic module and said driving module is provided with a chamber for accommodating said electric cord or part of it.

6. The photovoltaic charged driving device for shutter as claimed in claim 3, wherein said photovoltaic module comprising a frame having an opening, a solar panel and a rear cover, said rear cover and said frame are provided with plural projections and grooves for locking together to hold said solar panel therebetween and enable a solar cell surface of said solar panel exposed to sunlight through said opening to create power, electrodes of said solar panel are linked by conducting lines respectively to said power output terminal so as to be connected to said power input terminal of said driving module for charging.

7. The photovoltaic charged driving device for shutter as claimed in claim 1, wherein said rechargeable power unit is a chargeable battery or a super capacitor.

8. A photovoltaic charged driving device, installed on a preset location of a shutter and connected with one of slats of said shutter to drive it to rotate, said slats being linked together by a pulling rod so as to be simultaneously rotated by said driving device, said driving device comprising:
a driving module fixed in a recess of a side frame of said shutter to adjust an angle of said slats and provided with an output shaft connected to one end of one said slat, a rechargeable power unit, a controller, a motor and a power input terminal;
a photovoltaic module including a solar panel used for receiving sunlight, a power output terminal connected to said solar panel so as to charge said rechargeable power unit;
an electric cord fixedly connected between said power output terminal and said power input terminal; and
connecting means to selectively connect and disconnect said photovoltaic module and said driving module.

9. The photovoltaic charged driving device for shutter as claimed in claim 8, wherein said connecting means are corresponding locking hooks and grooves formed on said photovoltaic module and said driving module.

10. The photovoltaic charged driving for shutter as claimed in claim 8, wherein said electric cord is a spirally extensible structure.

11. The photovoltaic charged driving device for shutter as claimed in claim 8, wherein at least one of said photovoltaic module and said driving module is provided with a chamber for accommodating said electric cord or part of it.

12. The photovoltaic charged driving device for shutter as claimed in claim 8, wherein said photovoltaic module comprising a frame having an opening, a solar panel and a rear cover, said rear cover and said frame are provided with plural projections and grooves for locking together to hold said solar panel therebetween and enable a solar cell surface of said solar panel exposed to sunlight through said opening to create power, electrodes of said solar panel are linked by conducting lines respectively to said power output terminal so as to be connected to said power input terminal of said driving module for charging.
